(19) United States
(12) Patent Application Publication
(10) Pub. No.: US 2024/0120181 A1
(43) Pub. Date: Apr. 11, 2024

(54) System and Method for Plasma Process Uniformity Control

(71) Applicant: Tokyo Electron Limited, Tokyo (JP)

(72) Inventors: Sergey Voronin, Albany, NY (US); Qi Wang, Albany, NY (US)

(21) Appl. No.: 17/961,335

(22) Filed: Oct. 6, 2022

(51) Int. Cl. H01J 37/32; H01L 21/683

(52) U.S. Cl. CPC H01J 37/32715; H01L 21/6831; H01J 37/321; H01J 2237/3346

(57) ABSTRACT

A method of plasma processing includes delivering direct current voltage to a substrate holder including an upper side configured to support a substrate disposed within a plasma processing chamber. The upper side is divided into a plurality of zones by a plurality of conductors electrically isolated from each other. The method further includes pulsing the direct current voltage as first direct current pulses to a first conductor of the plurality of conductors using first pulse parameters, and pulsing the direct current voltage as second direct current pulses to a second conductor of the plurality of conductors using second pulse parameters that are different from the first pulse parameters. The direct current voltage is pulsed to the second conductor while pulsing the direct current voltage to the first conductor.

### TECHNICAL FIELD

The present invention relates generally to plasma processing, and, in particular embodiments, to a system and method for controlling process uniformity across a substrate during the plasma process.

### BACKGROUND

Device formation within microelectronic workpieces may involve a series of manufacturing techniques including formation, patterning, and removal of a number of layers of material on a substrate. In order to achieve the physical and electrical specifications of current and next generation semiconductor devices with the desired throughput, processing equipment and methods that are able to maintain a high degree of uniformity across all regions of the substrate are desirable. As device structures densify and critical dimensions shrink, precise control over processing conditions is necessary because even small variations during processing may result in nonfunctional or malfunctional devices.

Although great care is taken to design plasma processing apparatuses and plasma processes to be uniform across all regions of the substrate, conditions such as local plasma properties vary across the area of the substrate. Variation in plasma uniformity may occur for a variety of reasons, such as how the plasma is generated or the geometry of the plasma processing apparatus itself, among others. Further, uniformity may be more difficult to achieve for larger substrates. Larger substrates are desirable to increase throughput and lower costs. Therefore, systems and methods that are able to control process uniformity during plasma processing is desirable.

### SUMMARY

In accordance with an embodiment of the invention, a method of plasma processing includes delivering direct current voltage to a substrate holder including an upper side configured to support a substrate disposed within a plasma processing chamber. The upper side is divided into a plurality of zones by a plurality of conductors electrically isolated from each other. The method further includes pulsing the direct current voltage as first direct current pulses to a first conductor of the plurality of conductors using first pulse parameters, and pulsing the direct current voltage as second direct current pulses to a second conductor of the plurality of conductors using second pulse parameters that are different from the first pulse parameters. The direct current voltage is pulsed to the second conductor while pulsing the direct current voltage to the first conductor.

In accordance with another embodiment of the invention, a plasma processing apparatus includes a plasma processing chamber, a substrate holder including an upper side configured to support a substrate disposed within the plasma processing chamber, a direct current power supply coupled to the substrate holder with no intervening impedance matching network, and a controller operatively coupled to the plurality of zones and configured to pulse direct current voltage from the direct current power supply. The upper side is divided into a plurality of zones. The controller is configured to pulse the direct current voltage to each of the plurality of zones using corresponding independently selectable pulse parameters.

In accordance with still another embodiment of the invention, a substrate holder includes a holder assembly including an upper side configured to support a substrate disposed within a plasma processing chamber, a plurality of conductors electrically isolated from each other and disposed in the holder assembly at or below the upper side, a plurality of switches disposed within the holder assembly, at least one power input coupled to the plurality of switches and configured to provide bias power to the plurality of conductors, and a plurality of control inputs each coupled to a corresponding switch of the plurality of switches. The upper side is divided into a plurality of zones by the plurality of conductors. Each of the plurality of switches is coupled to a corresponding one of the plurality of conductors. Each of the plurality of control inputs is configured to toggle the corresponding switch between an ON state allowing the bias current to flow and an OFF state disallowing the bias current to flow.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate a schematic diagram of an example substrate holder including a plurality of zones with independently selectable bias pulse parameters configured to control plasma uniformity where FIG. 1A shows a side view of the substrate holder and FIG. 1B shows a top view of the substrate holder in accordance with embodiments of the invention;

FIG. 2 illustrates a schematic diagram of an example substrate holder including a plurality of switches in accordance with embodiments of the invention;

FIG. 3 illustrates a schematic diagram of an example plasma processing apparatus that includes a substrate holder with a plurality of switches configured to control plasma uniformity and coupled to a direct current power supply and a controller in accordance with embodiments of the invention;

FIG. 4 illustrates a schematic diagram of an example plasma processing apparatus that includes a substrate holder configured to control plasma uniformity by receiving direct current voltage pulses that are controlled externally in accordance with embodiments of the invention;

FIG. 5 illustrates a circuit diagram of an example switch including transistors and diodes in accordance with embodiments of the invention;

FIG. 6 illustrates a schematic diagram of an example substrate holder including a plurality of concentric zones in accordance with embodiments of the invention;

FIG. 7 illustrates a schematic diagram of another example substrate holder including a plurality of concentric zones in accordance with embodiments of the invention;

FIG. 8 illustrates a schematic diagram of yet another example substrate holder including a plurality of concentric zones in accordance with embodiments of the invention;

FIG. 9 illustrates a schematic diagram of still yet another example substrate holder including a plurality of concentric zones in accordance with embodiments of the invention;

FIG. 10 illustrates a schematic diagram of an example substrate holder including a plurality of azimuthal zones in accordance with embodiments of the invention;

FIG. 11 illustrates a schematic diagram of an example substrate holder including a plurality of concentric zones divided into a plurality of azimuthal segments in accordance with embodiments of the invention;

FIG. 12 illustrates a schematic diagram of an example substrate holder including a central zone and a plurality of concentric zones divided into a plurality of azimuthal segments in accordance with embodiments of the invention;

FIG. 13 illustrates a schematic diagram of an example substrate holder including a plurality of concentric zones having a subset divided into a number of azimuthal segments and another subset divided into another number of azimuthal segments in accordance with embodiments of the invention;

FIG. 14 illustrates a schematic timing diagram of an example of pulsed bias power including first bias pulses having a first duty cycle concurrently pulsed with second bias pulses having a different second duty cycle in accordance with embodiments of the invention;

FIG. 15 illustrates a schematic timing diagram of an example of pulsed bias power including first bias pulses having a first pulse frequency concurrently pulsed with second bias pulses having a different second pulse frequency in accordance with embodiments of the invention;

FIG. 16 illustrates a schematic timing diagram of an example of pulsed bias power including first bias pulses concurrently pulsed with second bias pulses having a dynamically adjusted duty cycle in accordance with embodiments of the invention;

FIG. 17 illustrates a schematic timing diagram of an example of pulsed bias power including bias pulse used to control radial process uniformity and azimuthal radial process uniformity in accordance with embodiments of the invention;

FIG. 18 illustrates a schematic timing diagram of an example of pulsed bias power including first bias pulse trains having a first pulse train length and second bias pulse trains having a different second pulse train length in accordance with embodiments of the invention;

FIG. 19 illustrates a schematic diagram of an example plasma processing apparatus including an inductive plasma source in accordance with embodiments of the invention;

FIG. 20 illustrates a schematic diagram of an example plasma processing apparatus including a capacitive plasma source in accordance with embodiments of the invention; and

FIG. 21 illustrates an example method of plasma processing in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The Moore's law extension in the semiconductor industry requires processing of features at nanometer scale. Scaling boosters for the node beyond 2 nm require angstrom scale tolerance with relevant uniformity within 300 mm wafer. This type of process uniformity is very challenging to achieve and is not possible with conventional plasma processing systems and methods. Therefore greater control over process uniformity is desirable for both increasing yield and quality of current devices and for making possible future devices.

The majority of conventional methods for process uniformity control are based on the plasma density uniformity distribution in a process chamber. One conventional technique for improving the plasma uniformity is to split radio frequency (RF) bias power between two zones of an electrostatic chuck (ESC). However, this method may be inefficient as a result of non-ideal impedance matching to the load. Additionally, the power delivery network becomes very complex with just two zones. Increasing the number of zones past two may be prohibitively complex. Therefore, even though more zones would improve the control over process uniformity, conventional methods are very limited to two zones by practical considerations.

Accordingly, embodiments described herein provide systems and methods for plasma processing that allow simultaneous control of pulse parameters of pulsed bias power over multiple zones of a substrate holder such as an ESC. The bias power may be pulsed direct current (DC) power in various embodiments. A plurality of switches may be included in the substrate holder to allow control over the pulse parameters in each of the multiple zones. For example, the switches may be electronic switches implemented using transistors such as metal-oxide-semiconductor field-effect transistors (MOSFETs). The bias power may be delivered to the substrate holder at a single bias power input. The multiple zones may be concentric to enable control over radial process uniformity and/or may be divided into azimuthal segments to enable control over azimuthal process uniformity.

Control over the bias power in multiple zones may advantageously allow precise control over ion energy across all regions of the substrate. This may have the benefit of increasing tool performance for plasma processes such as etching and deposition processes. For example, carefully controlling ion energy is desirable to improve etch selectivity and to achieve the desired interactions at the substrate surface.

For DC power embodiments, the use of DC pulse technology is advantageously free of various key disadvantages of conventional RF biasing, such as undesirable bi-modal ion energy distribution, standing wave effects that decrease uniformity, and the need for complex impedance matching network to couple the RF power to the substrate holder. Further, impedance matching carries with it additional related issues that are also undesirable such as reflected power overshoots, matching that is not immediate (or quick enough), and others.

DC power may also have the advantage of operation simplicity. For example, since the maximum ion energy is approximately equal to the voltage of the DC pulse, a collisionless sheath may be formed. Another possible benefit is that all of the ions from the plasma get the same accelerating voltage. DC pulses may also have minimal power losses because of the on/off nature of pulsed DC power.

For embodiments that use internal switches, the proximity of the switches to conductors that are used to define the multiple zones may have the advantage of efficiently delivering the desired power to the conductors with minimum distortion of the waveform which can occur with L/C parameters of long wires. The built-in nature of the switches also has the advantage of simplicity. The switches can beneficially be made powerful and compact, such as when using MOSFET-based transistor switches.

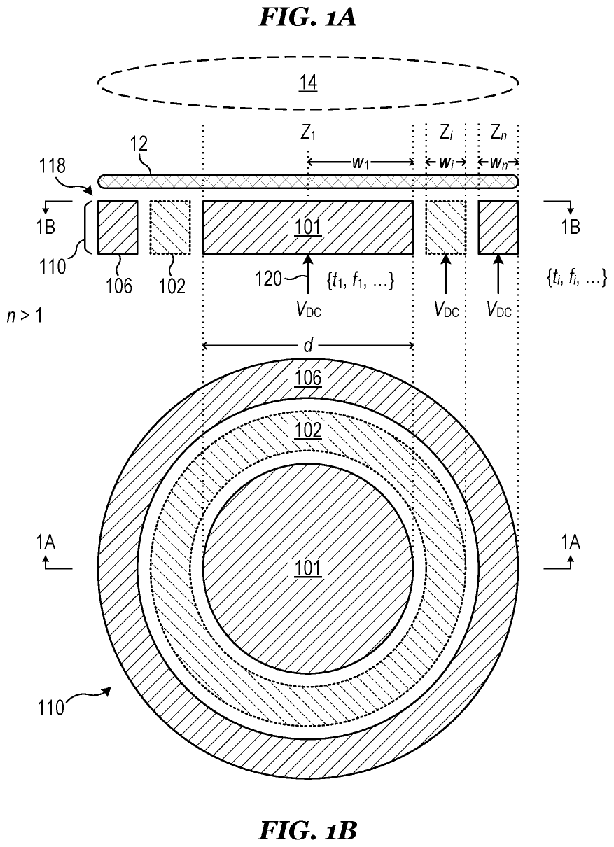

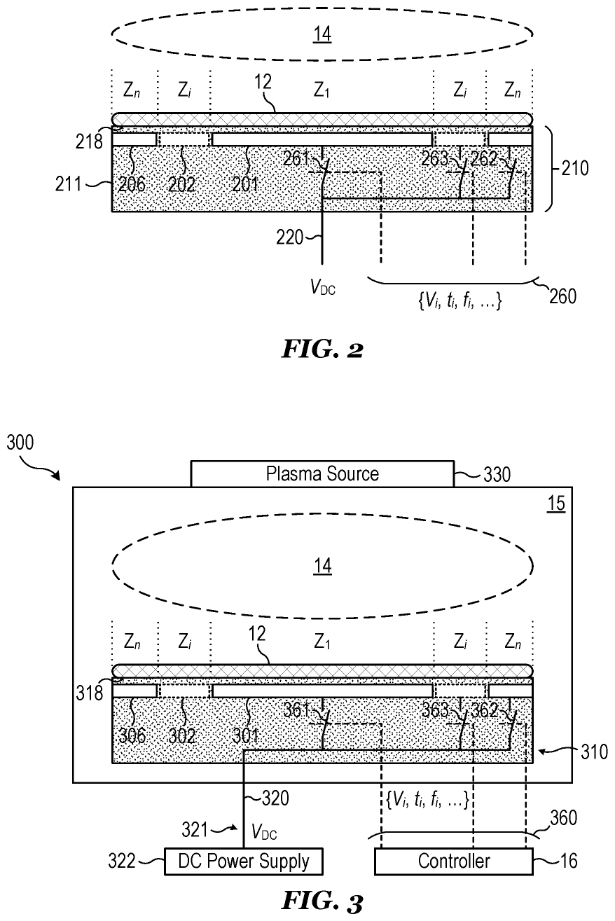

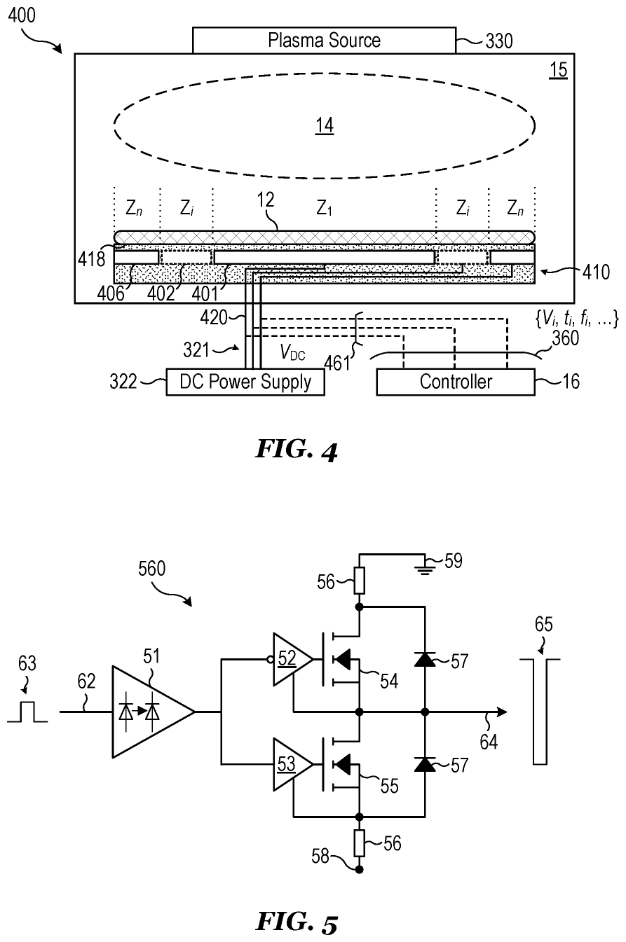

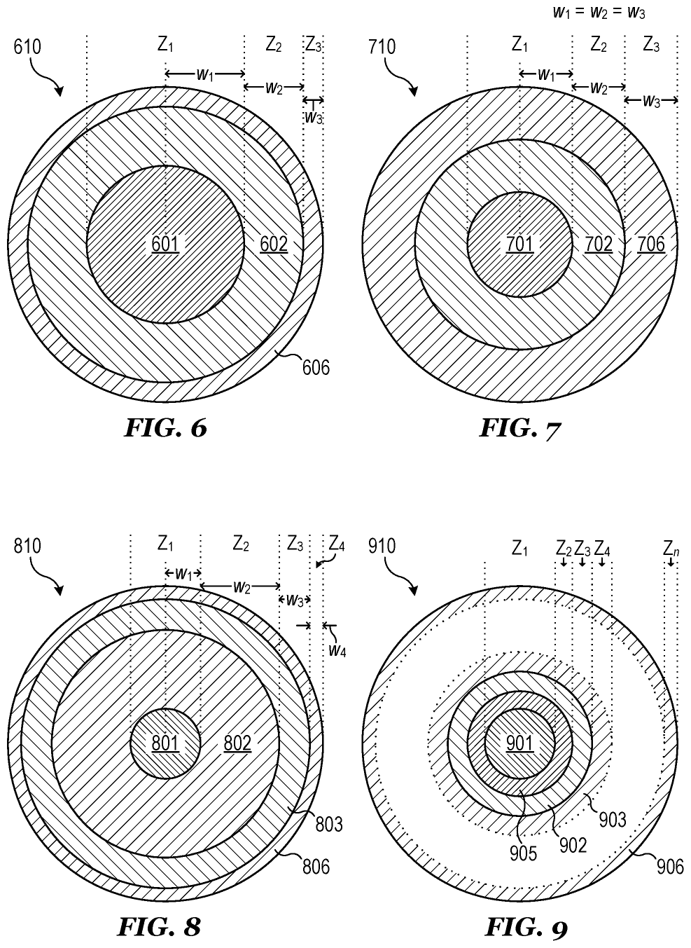

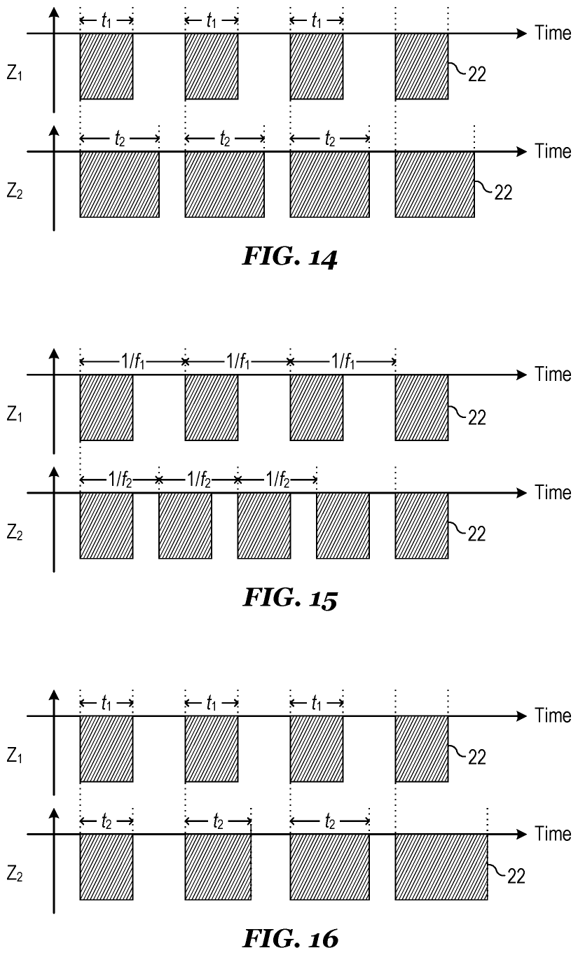

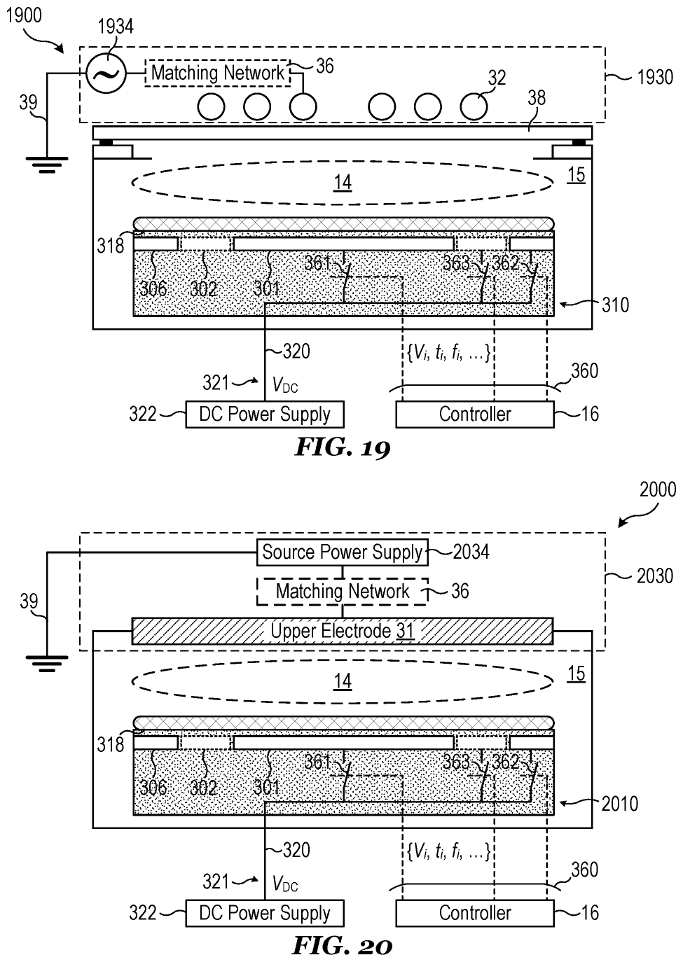

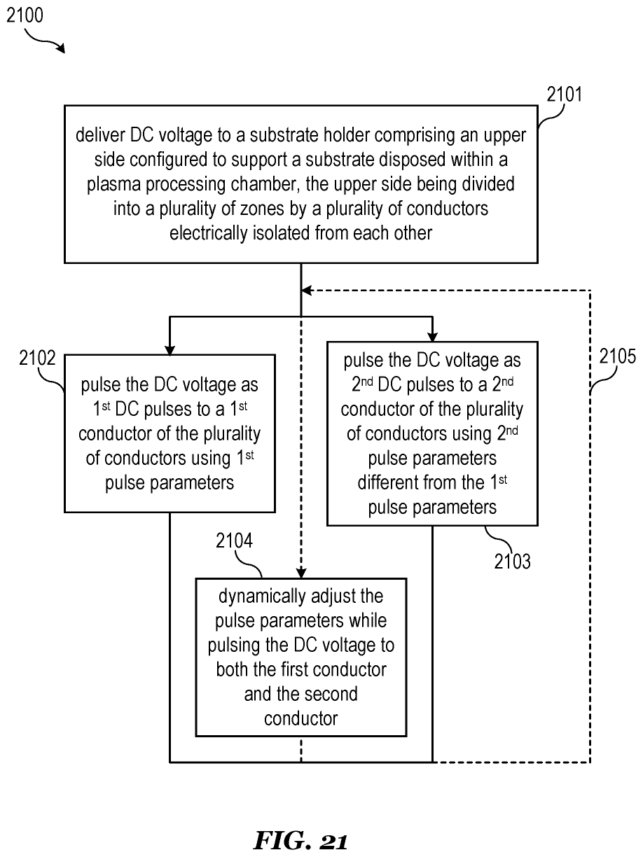

Embodiments provided below describe various systems and methods for plasma processing, and in particular, systems and methods that include simultaneous control of pulse parameters of pulsed bias power over multiple zones of a substrate holder. The following description describes the embodiments. FIGS. 1A and 1B are used to describe an example substrate holder. Another example substrate holder is described using FIG. 2. Two example plasma processing apparatuses are described using FIGS. 3 and 4. An example switch is described using FIG. 5. FIGS. 6-13 are used to describe example substrate holders with zones in various configurations. Several examples of pulses bias power are described using FIGS. 14-18. Two more example plasma processing apparatuses are described using FIGS. 19 and 20 while and example method of plasma processing is described using FIG. 21.

FIGS. 1A and 1B illustrate a schematic diagram of an example substrate holder including a plurality of zones with independently selectable bias pulse parameters configured to control plasma uniformity where FIG. 1A shows a side view of the substrate holder and FIG. 1B shows a top view of the substrate holder in accordance with embodiments of the invention.

Referring to FIGS. 1A and 1B, a substrate holder 110 includes an upper side 118 configured to support a substrate 12. For example, the substrate 12 (e.g. a wafer) may be supported by the substrate holder 110 to allow the substrate 12 to be processed using a plasma 14. For example, the substrate holder 110 may be included in a plasma processing chamber of a plasma processing apparatus. The substrate holder 110 may be any suitable type, and is an electrostatic chuck (ESC) in one embodiment. Other types of substrate holder may include vacuum chucks, mechanical clamps, and others.

The upper side 118 is divided into plurality of zones {Z₁, . . . , Zᵢ, . . . , Zₙ}. The number of zones is n where n>1 and Zᵢ is the i^{th} zone. In one embodiment, the total area of the plurality of zones closely corresponds with the area of the substrate 12. In other embodiments, the plurality of zones may correspond with only a portion of the area of the substrate 12.

The substrate holder 110 has at least one power input 120 configured to receive bias power (e.g. DC power to deliver DC voltage V_{DC}, but could also be RF power in some applications). While the power input 120 is shown as multiple inputs (e.g. from one or more bias power supplies), it may also be a single input. The substrate holder 110 is configured to supply the bias power as bias pulses (e.g. DC voltage pulses) to each zone Zᵢ of the plurality of zones with independently selectable pulse parameters {tᵢ, fᵢ, . . . }. This may be accomplished, for example, by a plurality of conductors electrically isolated from one another (e.g. as part of a holder assembly). The spatial control over pulse parameters may advantageously allow control over the process uniformity across the substrate 12.

In the specific example illustrated, the substrate holder 110 includes a central conductor 101 surrounded by an edge conductor 106. At least one interior conductor 102 may also be included. The plurality of conductors may be arranged as concentric conductors as shown or may be any variety of other shapes, the details of which may depend on a given application. Another arrangement that may be used in the alternative or may be incorporated along with concentric conductors is an azimuthal arrangement. Concentric zones may advantageously enable radial process control while azimuthal zones may enable azimuthal process control. Of course, other arrangements are possible, such as Cartesian arrangements or even irregular arrangements based on systemic asymmetric plasma non-uniformities.

The bias pulses for each of the zones are defined by a set of independently selectable parameters. For example, the pulse parameters include at least a parameter related to the number of pulses applied in a given time (e.g. pulse frequency fᵢ) and a parameter related the pulse duration. The pulse frequency may also be expressed as a duration: the period 1/fᵢ. The pulse duration parameter may be itself defined as a duration or may be defined as a percentage of the period. For convenience, the pulse duration parameter will be described herein as a percentage of the period 1/fᵢ, written as the duty cycle tᵢ. For example, the bias pulses applied to the first (central) zone Z₁ may be defined by the pulse parameters{t₁, f₁, . . . } including a first duty cycle t₁ and a first pulse frequency f₁ in addition to other optional pulse parameters. One or both of the pulse frequency fᵢ and the duty cycle tᵢ may be independently selectable.

The pulse parameters may also include other various optional parameters that further define the bias pulses. For example, the pulse parameters may include a parameter related to the magnitude of the pulses such as voltage Vᵢ in the case of DC pulses (as shown in the specific example) or the power (i.e. average wattage controlled by waveforms, phase shift, and duty cycle) delivered by the RF pulses. In practice, the power of the RF pulses may be the parameter that is directly controlled. RF pulses may also include a DC offset. It should be noted that while the bias pulses will always have an associated magnitude, such as voltage Vᵢ, the voltage may be controlled by the supplied bias power and therefore may not always be an independently selectable pulse parameter.

The pulse frequency fᵢ for any zone Zᵢ may be any suitable value and may depend on the specific details of a given application. In various embodiments each of the pulse frequencies fᵢ is greater than about 10 kHz. In some embodiments, each of the pulse frequencies fᵢ is less than about 10 MHz. In one embodiment, the pulse frequencies fᵢ are in the range from about 10 kHz to about 10 MHz. The duty cycle tᵢ for any zone Zᵢ can be any suitable duty cycle greater than 0% and less than 100% of the period 1/fᵢ.

The bias pulses may also be applied to the plurality of zones {Z₁, Zₙ} as a series of pulse trains. That is, each pulse train is defined by a duty cycle tᵢ and a pulse frequency fᵢ and applied for a pulse train duration at a pulse train frequency. For example, the additional pulse parameters used to define pulse trains may include pulse train length lᵢ and pulse train frequency Fᵢ. Because the pulse trains include bias pulses applied at a pulse frequency fᵢ, the pulse train frequency Fᵢ may be lower than fᵢ, but may be any suitable value otherwise. In various embodiments, the bias power is pulsed as a series of pulse trains that each have a pulse train frequency Fᵢ greater than about 1 Hz. In some embodiments, the each of the pulse train frequencies Fᵢ is less than about 100 kHz. In one embodiment, each of the pulse train frequencies Fᵢ is in the range from about 1 Hz to about 10 kHz.

Control over the bias pulses applied the plurality of zones {Z₁, Zₙ} may be accomplished internally using circuitry included in the substrate holder 110 to manipulate the provided DC voltage V_{DC} or externally by forming the bias pulses before supplying them directly to the substrate holder 110. In various embodiments, the provided DC voltage V_{DC} is altered by circuitry within the substrate holder 110, such as by a plurality of switches that are controlled using a plurality of control inputs. The implementation of the switches may be application specific, but may include electronic switches (such as power transistors) in some embodiments, and includes MOSFETs in one embodiment. Other implementations may use other electronic switching elements.

In the specific example of zones defined using a plurality of concentric conductors shown, the width of the conductors may be chosen to provide the desired radial process control based on the characteristics of the plasma 14. For instance, the plasma 14 may be known or measured to be non-uniform in some fashion at the edges of the substrate 12 relative to the center of the substrate 12. In some cases, the plasma 14 may be the most uniform in the center and may gradually decrease in uniformity the farther from the center. Various factors may affect the uniformity of the plasma 14 making adjustments to control the plasma uniformity desirable.

In the case of a circular substrate holder (other substrate holder shapes are of course possible) with concentric conductors, the size of the each conductor may be defined as a radial width wᵢ. For example, the edge conductor 106 has an edge width wₙ while optionally included interior conductors 102 have corresponding interior widths. The central conductor 101 has a diameter d and the radius of the central conductor 101 is a special case of a radial width where there is no opening in the center yielding a central radius w₁. The specific relative values of the central radius and the radial widths may depend on the degree and distribution of radial uniformities for a given plasma 14.

FIG. 2 illustrates a schematic diagram of an example substrate holder including a plurality of switches in accordance with embodiments of the invention. The substrate holder of FIG. 2 may be a specific implementation of other substrate holders described herein such as the substrate holder of FIG. 1, for example. Similarly labeled elements may be as previously described.

Referring to FIG. 2, a substrate holder 210 includes a holder assembly 211 including an upper side 218 configured to support a substrate 12. The substrate 12 may be disposed within a plasma processing chamber, for example. A plurality of conductors (e.g. a central conductor 201, an edge conductor 206, and one or more optional interior conductors 202) are electrically isolated from each other and disposed in the holder assembly 211 at or below the upper side 218. The upper side 218 is divided into a plurality of zones {Z₁, Zₙ} by the plurality of conductors.

It should be noted that here and in the following a convention has been adopted for brevity and clarity wherein elements adhering to the pattern [x10] where ‘x’ is the figure number may be related implementations of a substrate holder in various embodiments. For example, the substrate holder 210 may be similar to the substrate holder 110 except as otherwise stated. An analogous convention has also been adopted for other elements as made clear by the use of similar terms in conjunction with the aforementioned numbering system.

A plurality of switches (e.g. a first switch 261, a second switch 262, and a third switch 263 corresponding to the central conductor 201, the edge conductor 206, and an interior conductor 202) is disposed within the holder assembly 211. Each of the plurality of switches is coupled to a corresponding one of the plurality of conductors. At least one power input 220 is coupled to the plurality of switches and configured to supply bias power (e.g. DC power) to deliver DC voltage V_{DC} the plurality of conductors. A plurality of control inputs, each of which is coupled to a corresponding switch of the plurality of switches, is configured to toggle the corresponding switch between an ON state allowing the bias current to flow and an OFF state disallowing the bias current to flow.

The DC power input 220 is illustrated in this specific example as being a single power input that is internally branched to supply power to each of the plurality of conductors. In this configuration, the voltage of the bias pulses may have substantially the same magnitude (e.g. equal voltage parameters in the case of DC pulses). For example, this may be by virtue of being fed from the same power supply and having only switches as internal circuitry (although of course voltage altering circuitry could of course be included). However, in some embodiments, the substrate holder 210 may receive bias power from multiple power inputs. In this configuration, the voltage of the bias pulses may be made different at one or more of the power inputs.

FIG. 3 illustrates a schematic diagram of an example plasma processing apparatus that includes a substrate holder with a plurality of switches configured to control plasma uniformity and coupled to a direct current power supply and a controller in accordance with embodiments of the invention. The plasma processing apparatus of FIG. 3 may include any of the substrate holders as described herein, such as either of the substrate holders of FIG. 1 or 2, as examples. Similarly labeled elements may be a previously described.

Referring to FIG. 3, a plasma processing apparatus 300 includes a plasma processing chamber 15 configured to contain a plasma 14 for processing a substrate 12 supported by a substrate holder 310. The plasma 14 is provided by a plasma source 330 and may be any type of plasma. For example, the plasma source 330 may be an inductively coupled plasma (ICP) source, a capacitively coupled plasma (CCP) source, a surface wave plasma (SWP) source, a helical resonator source, and the like. Additionally, the plasma source 330 may generate the plasma 14 inside the plasma processing chamber 15 or may be a remote plasma source fluidically coupled to the plasma processing chamber 15 so as to deliver the plasma 14 into the plasma processing chamber 15.

As before, the upper side 318 of the substrate holder 310 is divided into a plurality of zones (e.g. concentric, azimuthal, etc.) that are configured to receive bias power and are coupled to a DC power supply 322. The DC power supply 322 is coupled to the substrate holder 310 at a DC power input 320 with no intervening impedance matching network (indicated by arrow 321). However, in some alternative implementations, the DC power supply 322 may be replaced with an RF power supply. In these applications, an optional bias match network may be included between the power input 320 and the RF power supply because impedance matching may be desirable.

Here, the specific implementation of the zones is not shown and may vary based on the specifics of a given application. The substrate holder 310 is configured to deliver DC voltage pulses each zone Zᵢ according to independent selectable pulse parameters {Vᵢ, tᵢ, fᵢ, . . . }. A controller 16 is operatively coupled to the substrate holder 310 and is configured to control the bias pulses using at least one control input 360.

The DC voltage pulses may be formed internally (as shown) or may be formed externally and then supplied to the substrate holder 310 (as shown in FIG. 4). In particular, additional external equipment or circuitry may be included to transform the supplied DC power into DC voltage pulses with pulse parameters that are independently selectable for each zone Zᵢ. Further, it may also be possible in some applications to switch RF power for multiple zones. For example, one or more intervening function generators and/or pulse modulation circuits may be included that are controlled by the controller 16.

The plasma processing apparatus 300 may be used to perform methods of plasma processing. For example, one specific example of a method of plasma processing includes a step of delivering the DC voltage V_{DC} to the substrate holder 310 including the upper side 318 configured to support the substrate 12 disposed within the plasma processing chamber 15. The upper side 318 is divided into a plurality of zones by a plurality of conductors electrically isolated from each other (e.g. a central conductor 301, an edge conductor 306, and one or more optional interior conductors 302 as shown). A plurality of switches may also be included (e.g. a first switch 361, a second switch 362, and one or more optional third switches 363 corresponding to the central conductor 301, the edge conductor 306, and any interior conductors 302).

The method further includes the steps of pulsing the DC voltage V_{DC} as first DC pulses to a first conductor (e.g. central conductor 301 such as by using a first switch 361) of the plurality of conductors using first pulse parameters {V₁, t₁, f₁, . . . } and pulsing the DC voltage V_{DC} as second DC pulses to a second conductor (e.g. edge conductor 306 such as by using a third switch 363) of the plurality of conductors using second pulse parameters {V₂, t₂, f₂, . . . } different from the first pulse parameters. For example, one or more of V₁≠V₂, t₁≠t₂, and f₁≠f₂. The pulsing steps are performed concurrently, that is, the DC voltage is pulsed to the second conductor while pulsing the DC voltage to the first conductor.

FIG. 4 illustrates a schematic diagram of an example plasma processing apparatus that includes a substrate holder configured to control plasma uniformity by receiving direct current voltage pulses that are controlled externally in accordance with embodiments of the invention. The plasma processing apparatus of FIG. 4 may be a specific implementation of other plasma processing apparatuses described herein such as the plasma processing apparatus of FIG. 3, for example. Similarly labeled elements may be as previously described.

Referring to FIG. 4, a plasma processing apparatus 400 includes a plasma processing chamber 15 configured to contain a plasma 14 for processing a substrate 12 as previously discussed. The substrate 12 is supported by a substrate holder 410, which may be a specific implementation of the substrate holder 110 of FIG. 1, for example. The substrate holder 410 includes an upper side 418 configured to support the substrate 12, which is disposed within the plasma processing chamber 15. The upper side is divided into a plurality of zones {Z₁, Zₙ}. A DC power supply 322 is coupled to the substrate holder 410 at a DC power input 420 with no intervening impedance matching network (indicated by arrow 321). A controller 16 is operatively coupled to the plurality of zones using a plurality of control inputs 360 and is configured to pulse DC voltage V_{DC} from the DC power supply 322 to each of the plurality of zones Zᵢ using corresponding independently selectable pulse parameters.

For example, the independently selectable pulse parameters may include one or more of duty cycle tᵢ, pulse frequency fᵢ, and voltage Vᵢ, which is illustrated as {Vᵢ, tᵢ, fᵢ, . . . }. In some cases, the independently selectable pulse parameters include additional parameters, such as if the DC power is pulsed as pulse trains. As discussed as a possibility before, the DC pulses are externally controlled using optional external control inputs 461 in this specific example.

FIG. 5 illustrates a circuit diagram of an example switch including transistors and diodes in accordance with embodiments of the invention. The switch of FIG. 5 may be a specific implementation of other switches described herein such as the switches of FIG. 4, for example. Similarly labeled elements may be as previously described.

Referring to FIG. 5, a switch 560 includes a control signal input 62 coupled to inputs of both an inverter 52 and a buffer 53. In this specific example, the switch 560 is implemented as a half bridge MOSFET switch, but other configurations are possible as may be apparent to those of skill in the art. An opto-isolator 51 may be coupled between the control signal input 62 and the inputs of the inverter 52 and the buffer 53. The opto-isolator 51 may be used to electrically isolate the control circuitry from high voltage circuitry.

A transistor is coupled to each of the inverter 52 and the buffer 53, which act as drivers to control the transistors. Specifically, a first transistor 54 includes a control terminal (e.g. a gate) coupled to an output of the inverter 52, a first input/output terminal (e.g. source/drain) coupled to a reference voltage 59, and a second input/output terminal (e.g. drain/source) coupled to a second transistor 55. The second transistor 55 includes a control terminal coupled to an output of the buffer 53, a first input/output terminal coupled to the first transistor 54, and a second input/output terminal coupled to a high voltage input 58. The

[symbol]

One or more resistors 56 may be included in the switch 560. For example, a resistor 56 may be included between the first transistor 54 and the reference voltage 59. Additionally or alternatively, a resistor 56 may be included between the second transistor 55 and the high voltage input 58. The resistors 56 that are shown may be included for minimizing current overshoot to protect the transistors from high currents during switching transitions. Other resistors may also be included as may be apparent to one of skill in the art, such as to achieve desired current characteristics at various locations in the circuit.

Two diodes 57 are coupled to the transistors. In practice, these diodes may be part of a transistor assembly (e.g. a single component). Whether integrated or separate, a first diode is coupled between the first and second input/output terminals of the first transistor 54 while a second diode is coupled between the first and second input/output terminals of the second transistor 55. A high voltage output 64 is coupled to the second input/output terminal of the first transistor 54, the first input/output terminal of the second transistor 55, and both the first and second diodes 57.

The switch 560 is configured to receive a control signal 63 at the control signal input 62 and output a high voltage signal 65 at the high voltage output 64. For example, the control signal 63 may be a low voltage signal that corresponds with a desired pattern of bias pulses that are to be applied to a zone of a substrate holder, such as those described in the foregoing. The switch 560 is in either an ON state (bias current flows through the switch 560 and there is a non-zero voltage at the high voltage output 64) or an OFF state (no bias current flows through the switch 560 and there is zero voltage at high voltage output 64). For example, when the control signal 63 is low, the switch 560 may be in the OFF state and toggle to the ON state when the control signal 63 is high (as shown). Alternatively, other implementations may have the opposite behavior.

The high voltage signal 65 has a higher voltage than the control signal 63. The voltage of the high voltage signal 65 may be substantially similar to the voltage of the high voltage input 58. For example, the high voltage input 58 may be coupled to a DC power supply that supplies a desired DC voltage for DC pulses that are output at the high voltage output 64. The sign of the voltage need not be the same. For example, as schematically illustrated, the control signal 63 is high when it has a low positive voltage resulting in a high voltage signal 65 that has a large negative voltage.

The switch 560 implemented as a half bridge switch is one example of many possible implementations of an electronic switch that includes transistors as switching elements. In this specific example, the transistors are MOSFETs. However, other transistors and switching elements are of course possible. For example, the transistors may also be insulated-gate bipolar transistors (IGBTs), bipolar junction transistors (BJTs), or other switching elements such as thyristors. Various implementations of electronic switches include power transistors, such as when dealing with high voltages and/or currents. For example, in this specific example, the MOSFETs may be power transistors.

While the reference potential 59 is shown here as grounded, the reference potential 59 may be positive or negative relative to the ground potential in some embodiments, in addition to being 0 V. The potential at the high voltage input 58 should be more negative than the reference potential 59 for this example configuration, but this may depend on a variety factors such as the type of switching elements used and the definition of logical high and low signals for the circuit. For example, one alternative situation may be that the OFF state switch voltage (reference potential 59) is positive (or even negative) while the ON state switch voltage (high voltage input 58) is highly negative.

The configuration of the plurality of zones at the upper side of the substrate holders described herein may have any suitable configuration as previously mentioned. Some possible options for various zone configurations are shown in the substrate holders of FIGS. 6-13, which are discussed in the following. The substrate holders of FIGS. 6-13 may each be a specific implementation of other substrate holders described herein such as the substrate holder of FIG. 1, for example. Moreover, the arrangements and concepts generally described in these specific examples may be combined and adapted to meet the desired specifications of a given application while remaining within the scope of the invention.

FIG. 6 illustrates a schematic diagram of an example substrate holder including a plurality of concentric zones in accordance with embodiments of the invention. Referring to FIG. 6, a substrate holder 610 includes three conductors in a concentric configuration similar to that shown in the substrate holder 110 of FIG. 1 where n=3. Specifically, the substrate holder 610 includes a plurality of concentric zones comprising a central zone Z₁ and an edge zone Z₃ surrounding the central zone. An interior zone Z₂ surrounds the central zone and is between the edge zone and the central zone. The zones are formed using a plurality of conductors of the substrate holder 610, which include a central conductor 601, an interior conductor 602, and an edge conductor 606, as shown.

The radial widths w₁, w₂, and w₃ of the conductors may be any suitable width and may depend on the specific non-uniformities associated with the plasma generated during a given plasma process. In this specific example, w₁>w₂>w₃. This configuration may reflect a plasma that with a radial non-uniformity profile that has a large mostly uniform central region and nonlinearly (e.g. exponentially) decreases in uniformity as the distance from the center of the substrate holder 610 increases.

The concentric configuration of the zones facilitates controlling radial process uniformity by pulsing bias power to the different zones using different pulse parameters for one or more of the zones.

FIG. 7 illustrates a schematic diagram of another example substrate holder including a plurality of concentric zones in accordance with embodiments of the invention. Referring to FIG. 7, a substrate holder 710 is a specific implementation of the substrate holder 610 including a central conductor 701, an interior conductor 702, and an edge conductor 706 in a concentric configuration where w₁=w₂=w₃. This configuration may reflect a plasma that with a radial non-uniformity profile that linearly decreases in uniformity as the distance from the center of the substrate holder 710 increases.

FIG. 8 illustrates a schematic diagram of yet another example substrate holder including a plurality of concentric zones in accordance with embodiments of the invention. Referring to FIG. 8, a substrate holder 810 includes four conductors in a concentric configuration similar to that shown in the substrate holder 110 of FIG. 1 where n=4. Specifically, the substrate holder 810 includes a plurality of concentric zones comprising a central zone Z₁, an inner interior zone Z₂, an outer interior zone Z₃, and an edge zone Z₄. The zones are formed using a plurality of conductors of the substrate holder 810, which include a central conductor 801, an inner interior conductor 802, an outer interior conductor 803, and an edge conductor 806, as shown.

Each of the plurality of conductors has a corresponding radial width as before. In this specific example, the radial width w₁ of the central conductor 801 is less than the radial width w₂ of the inner interior conductor 802. This configuration may be used if there is a region in the center of the plasma that exhibits increased non-uniformity relative to an inner interior region (e.g. that may be the most uniform region of the plasma). Similar to the substrate holder 610, the radial widths decrease nonlinearly from the inner interior conductor 802 to the edge of the substrate holder 810 (w₂>w₃>w₄).

FIG. 9 illustrates a schematic diagram of still yet another example substrate holder including a plurality of concentric zones in accordance with embodiments of the invention. Referring the FIG. 9, a substrate holder 910 is a generalized concentric configuration similar to that shown in the substrate holder 110 of FIG. 1 where n>4. The substrate holder 910 includes an inner central conductor 901 (Z₁), an outer central conductor 905 (Z₂) an inner interior conductor 902 (Z₃), an outer interior conductor 903 (Z₄), and an edge conductor 906 (Zₙ). Optionally, some number of additional interior conductors may be included between the outer interior conductor 903 and the edge conductor 906.

The substrate holder 910 is similar to the substrate holder 610, but where higher resolution may be is desired. That is, increasing the number of zones may advantageously allow for finer control over plasma uniformity. However, this may also increase cost and complexity of the substrate holder 910.

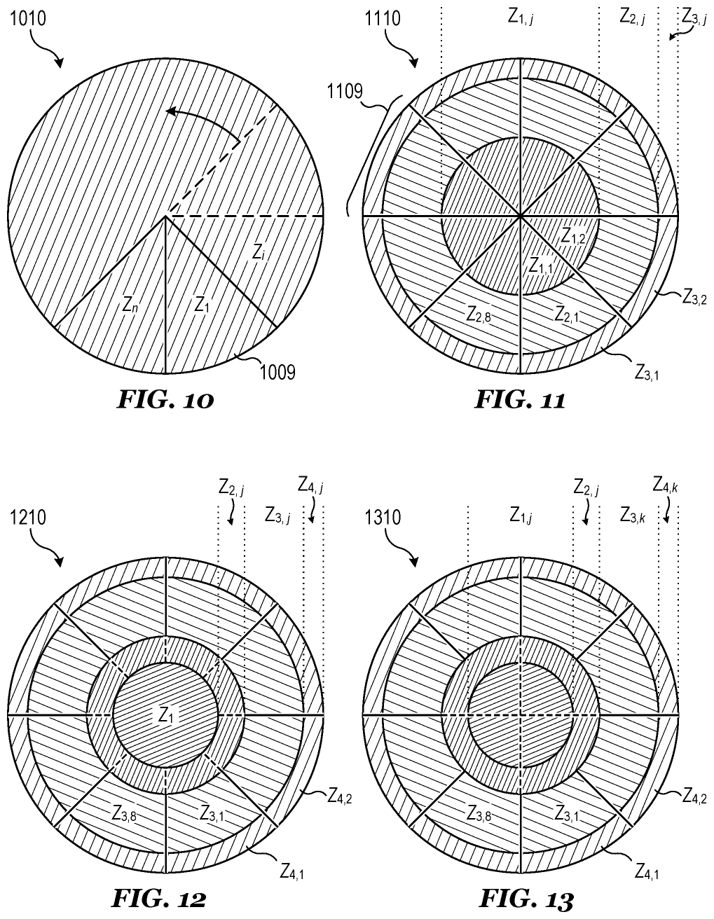

FIG. 10 illustrates a schematic diagram of an example substrate holder including a plurality of azimuthal zones in accordance with embodiments of the invention. Referring to FIG. 10, a substrate holder 1010 shows an additional or alternative configuration than the concentric configurations previously discussed. Specifically, the substrate holder 1010 includes a plurality of azimuthal zones that facilitate controlling azimuthal process uniformity. The plurality of azimuthal zones include a plurality of azimuthal segments 1009 that extend from a central point of the upper side to an edge of the substrate holder 1010.

As before, any number of azimuthal zones greater than one (n>1) are possible. For example, n=2 would be halves, n=3 would be thirds, n=4 would be quarters and so on. Although there is no requirement that the zones be uniform in size, this may be beneficial to afford accurate azimuthal control.

FIG. 11 illustrates a schematic diagram of an example substrate holder including a plurality of concentric zones divided into a plurality of azimuthal segments in accordance with embodiments of the invention. Referring to FIG. 11, a substrate holder 1110 includes a plurality of azimuthal zones divided into a plurality of concentric zones creating azimuthal segments 1109. This configuration combines the concentric and azimuthal configurations discussed thus far. For example, the substrate holder 1110 may be conceptually understood to be the combination of substrate holder 610 and substrate holder 1010, for example.

Since both radial and azimuthal divisions are included, control over both radial and azimuthal process uniformity may simultaneously be achieved. The zones may be labeled based on a concentric position and an azimuthal position. For example, the central zone is labeled Z_{1,j} where j is an index indicating the azimuthal position within the central zone (Z_{1,1}, Z_{1,2}, and so on). The interior zone and edge zone are labeled similarly as Z_{2,j} and Z_{3,j}, respectively. Although substrate holder 1110 is shown with three concentric zones and eight azimuthal zones, either number could be changed as desired.

FIG. 12 illustrates a schematic diagram of an example substrate holder including a central zone and a plurality of concentric zones divided into a plurality of azimuthal segments in accordance with embodiments of the invention. Referring to FIG. 12, a substrate holder 1210 is a generalized variation of the substrate holder 1110 where the azimuthal divisions do not extend all the way to the center of the substrate holder 1210. That is, at least a central zone of the substrate holder 1210 does not have azimuthal segments. This configuration may be useful if the size of the azimuthal segments becomes too small to be beneficial or are so small that undesirable effects occur electrically within the substrate holder, the substrate, or the plasma.

For example, the substrate holder 1210 includes a central zone Z₁ that is not divided azimuthally. In contrast, an outer interior zone Z_{3,j} and an edge zone Z_{4,j} are azimuthally divided as discussed previously. Any number of the concentric zones may be divided into azimuthal segments. For example, an inner interior zone Z_{2,j} is shown as optionally divided into azimuthal segments. Any of the other zones may also not be azimuthally divided if desired.

FIG. 13 illustrates a schematic diagram of an example substrate holder including a plurality of concentric zones having a subset divided into a number of azimuthal segments and another subset divided into another number of azimuthal segments in accordance with embodiments of the invention. Referring to FIG. 13, a substrate holder 1310 is another generalized variation of the substrate holder 1110 where the number of azimuthal divisions is different between one or more concentric zones. In this specific example, a central zone Z_{1,j} and an inner interior zone Z_{2,j} are each divided into j>1 azimuthal segments (e.g. j=4) while an outer interior zone Z_{3,k} and an edge zone Z_{4,k} are each divided in k>1 azimuthal segments (e.g. k=8) where j≠k.

This configuration may be another way of maintaining desired conductor/zone sizes while still enabling azimuthal control. As shown in this specific example of the substrate holder 1310, the central azimuthal segments are similar in size to the edge azimuthal segments. Of course, this concept is not limited to specific numbers of azimuthal segments or even a specific number of different azimuthal regions (here, two are shown as j and k, but more could be included as desired). Indeed, as previously mentioned, the configuration of the zones may depend on the specifics of a given application, even including irregularly-shaped zones or asymmetric zones if desired. Furthermore, any number of concentric zones may also be utilized, such as by combining the azimuthal configuration concepts shown in FIG. 13 with the generalized concentric configuration concepts shown in FIG. 9.

The bias pulses that are applied to the plurality of zones described herein may have any suitable combination of pulse parameters. Some possible options for bias pulse configurations are shown in the schematic timing diagrams of FIGS. 14-18, which are discussed in the following. The schematic timing diagrams of FIGS. 14-18 may each represent a specific implementation bias pulses applied to substrate holders described herein such as the substrate holder of FIG. 1, for example. Moreover, the arrangements and concepts generally described in these specific examples may be combined and adapted to meet the desired specifications of a given application while remaining within the scope of the invention.

FIG. 14 illustrates a schematic timing diagram of an example of pulsed bias power including first bias pulses having a first duty cycle concurrently pulsed with second bias pulses having a different second duty cycle in accordance with embodiments of the invention. Referring to FIG. 14, the schematic timing diagram illustrates bias power pulsed as bias pulses 22 to a first zone Z₁ with a first set of pulse parameters that include a first duty cycle t₁ and to a second zone Z₂ with a second set of pulse parameters that include a second duty cycle t₂ that is different than the first duty cycle t₁.

FIG. 15 illustrates a schematic timing diagram of an example of pulsed bias power including first bias pulses having a first pulse frequency concurrently pulsed with second bias pulses having a different second pulse frequency in accordance with embodiments of the invention. Referring to FIG. 15, the schematic timing diagram illustrates bias power pulsed as bias pulses 22 to a first zone Z₁ with a first set of pulse parameters that include a first pulse frequency f₁ and to a second zone Z₂ with a second set of pulse parameters that include a second pulse frequency f₂ that is different than the first pulse frequency f₁. As shown, the pulse frequency fᵢ is related to the period of the bias pulses (1/fᵢ).

It should be noted that more than one pulse parameter may be different. For example, both the duty cycle and the pulse frequency may be different for the bias pulses applied to Z₁ and Z₂. Additionally, other pulse parameters may be varied, such as voltage, pulse shape, and others.

FIG. 16 illustrates a schematic timing diagram of an example of pulsed bias power including first bias pulses concurrently pulsed with second bias pulses having a dynamically adjusted duty cycle in accordance with embodiments of the invention. Referring to FIG. 16 one example of dynamically adjusting pulse parameters is shown where the duty cycle t₂ of the bias pulses applied to Z₂ are dynamically adjusted while applying the bias pulses. This concept can be generalized to any pulse parameter. Further, the pulse parameters of any of the zones may be dynamically adjusted.

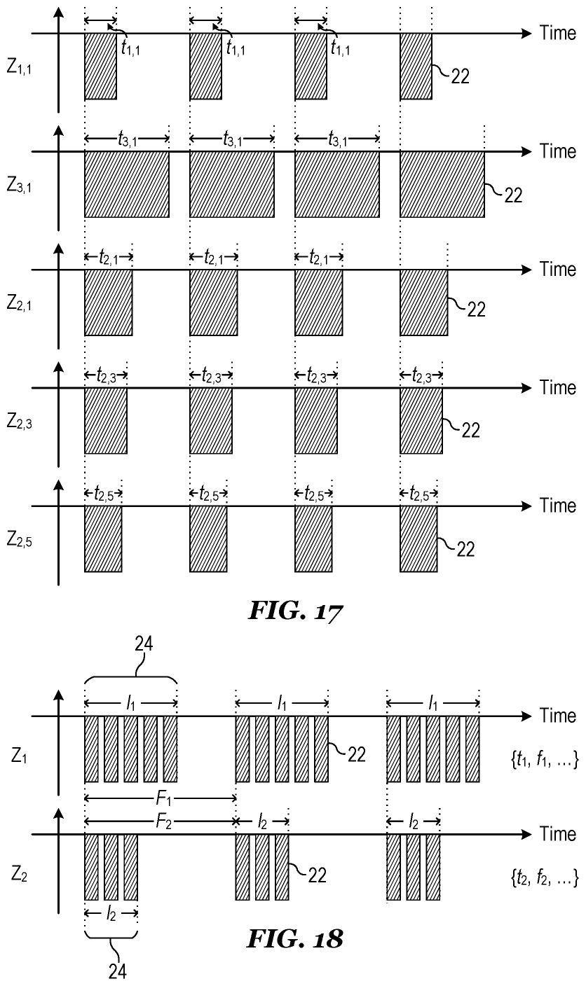

FIG. 17 illustrates a schematic timing diagram of an example of pulsed bias power including bias pulse used to control radial process uniformity and azimuthal radial process uniformity in accordance with embodiments of the invention. Referring to FIG. 17, a specific example including zones that afford both radial and azimuthal control is given. In this specific example, the duty cycle is varied for zones of a substrate holder having three concentric zones and eight azimuthal zones, but the concept equally applies to other pulse parameters and zone configurations. It should also be noted that while only five zones are shown as an example, the remaining zones are also receiving bias power and similar principles to those discussed below also apply to the remaining zones.

For the radial control, the duty cycle is adjusted to increase the duration of applied bias power for zones that are farther from the center. This may be used, for example, if the plasma density is greater in the center and decreases closer to the edge. For example, Z_{1,j} may be central zone having a first azimuthal segment Z_{1,1}. The bias power may be pulsed to Z₁ at a duty cycle t_{1,1} that is less than the duty cycle t_{2,1} pulsed to the first azimuthal segment Z_{2,1} of an interior zone, which in turn is less than the duty cycle t_{3,1} pulsed to the first azimuthal segment Z_{3,1} of an edge zone.

There may also be azimuthal differences in the uniformity of the plasma. For azimuthal control, the duty cycle can be adjusted further for different azimuthal segments (e.g. in addition to the radial adjustments that have already been made). To illustrate this concept, the bias pulses for three interior azimuthal segments Z_{2,1}, Z_{2,3}, and Z_{2,5} are shown. Various factors may cause plasma properties such as the plasma density be azimuthally asymmetric. For example, the plasma on one side of substrate holder (e.g. the side including the fifth azimuthal segment Z_{i,5}) may be more dense, requiring a shorter bias pulse to achieve process uniformity. Accordingly, the duty cycle t_{2,1} is greater that the duty cycle t_{2,5} applied to Z_{2,5}.

The azimuthal non-uniformity may be localized so as to only require adjustment in Z_{2,5} or may require adjustment across several azimuthal zones. For example, intermediate zones located between Z_{i,1} and Z_{i,5} may also be affected, perhaps to a lesser extent than Z_{i,5}. This is shown in the example by the bias pulses applied to Z_{2,3} having a duty cycle t_{2,3} less than t_{2,1} but greater than t_{2,5}.

FIG. 18 illustrates a schematic timing diagram of an example of pulsed bias power including first bias pulse trains having a first pulse train length and second bias pulse trains having a different second pulse train length in accordance with embodiments of the invention. Referring to FIG. 18, the bias pulses (e.g. DC pulses) may also be applied as a series pulse trains. The pulse trains may be defined by additional pulse parameters such as pulse train frequency Fᵢ and pulse train length h as shown. Like other pulse parameters, the pulse train parameters may be independently selectable between zones. For example, in this example, the pulse train length l₁ of the series of pulse trains applied to Z₁ is greater than the pulse train length l₂ of the series of pulse trains applied to Z₂.

FIG. 19 illustrates a schematic diagram of an example plasma processing apparatus including an inductive plasma source in accordance with embodiments of the invention. The plasma processing apparatus of FIG. 19 may be a more specific implementation of other plasma processing apparatuses described herein, such as the plasma processing apparatus of FIG. 2, for example. Similarly labeled elements may be as previously described.

Referring the FIG. 19, a plasma processing apparatus 1900 is a more specific implementation of the plasma processing apparatus 200 of FIG. 2 that includes an inductive plasma source 1930 configured to generate the plasma 14. The inductive plasma source 1930 includes a coil 32 coupled to an RF power supply 1934 (a source power supply) that is coupled to ground 39. An optional impedance matching network 36 may be included between the RF power supply 1934 and the coil 32. For example, impedance matching may be desirable to ensure efficient coupling of RF power to the coil 32. However, in some situations such as when the coil 32 is driven with RF power at a resonant frequency (or resonant harmonic) of the coil 32, the match network may be omitted.

The RF power supplied by the RF power supply 1934 to the coil 32 is inductively coupled to gas within the plasma processing chamber 15 through a dielectric 38. In this example, the plasma 14 is an inductively coupled plasma that is generated in the plasma processing chamber.

FIG. 20 illustrates a schematic diagram of an example plasma processing apparatus including a capacitive plasma source in accordance with embodiments of the invention. The plasma processing apparatus of FIG. 20 may be a more specific implementation of other plasma processing apparatuses described herein, such as the plasma processing apparatus of FIG. 2, for example. Similarly labeled elements may be as previously described.

Referring the FIG. 20, a plasma processing apparatus 2000 is a more specific implementation of the plasma processing apparatus 200 of FIG. 2 that includes a capacitive plasma source 2030 configured to generate the plasma 14. The capacitive plasma source 2030 includes an upper electrode 31 coupled to a source power supply 2034 that is coupled to ground 39. An optional impedance matching network 36 may again be included between the source power supply 2034 and the upper electrode 31. The substrate holder 2010 serves as a lower electrode for generating the plasma 14, which is a capacitively coupled plasma in this example.

FIG. 21 illustrates an example method of plasma processing in accordance with embodiments of the invention. The method of FIG. 21 may be combined with other methods and performed using the systems and apparatuses as described herein. For example, the method of FIG. 21 may be combined with the embodiment of FIGS. 1A and 1B as well as any of the embodiments of FIGS. 2-20. Although shown in a logical order, the arrangement and numbering of the steps of FIG. 21 are not intended to be limited. The method steps of FIG. 21 may be performed in any suitable order or concurrently with one another as may be apparent to a person of skill in the art.

Referring to FIG. 21, step 2101 of a method 2100 of plasma processing includes delivering DC voltage to a substrate holder. An upper side of the substrate holder is configured to support a substrate disposed within a plasma processing chamber. The upper side is divided into a plurality of zones by a plurality of conductors electrically isolated from each other.

In various embodiments, the plurality of zones includes a plurality of concentric zones that may advantageously enable control over radial process uniformity (e.g. etch uniformity). Additionally or alternatively, the plurality of zones may include a plurality of azimuthal zones that may advantageously enable control over azimuthal process uniformity. For example, the plurality of zones may include a plurality of concentric zones that are further divided into azimuthal segments allowing control over both radial and azimuthal process uniformity.

Step 2102 and step 2103 are performed concurrently. The DC voltage is pulsed in step 2102 as first DC pulses to a first conductor of the plurality of conductors using first pulse parameters. Similarly, step 2103 is to pulse the DC voltage as second DC pulses to a second conductor of the plurality of conductors using second pulse parameters that are different from the first pulse parameters. In particular, the difference between the first and second pulse parameters may have the benefit of allowing control over process uniformity.

The specific process uniformity control afforded by the pulsed DC voltage may depend on the geometry and arrangement of the plurality of conductors. Concentric conductors may allow pulsing the DC voltage as two or more sets of DC pulses to two or more conductors to control radial process uniformity. By the same token, azimuthal conductors may allow the pulsing to control azimuthal process uniformity. As already discussed, these geometries can also be combined allow control over both radial and azimuthal process uniformity.

The pulse parameters may include parameters such as duty cycle, pulse frequency, and voltage. More than one of the first pulse parameters may be different than the second pulse parameters. In one embodiment, the duty cycle of the first DC pulses and the duty cycle of the second DC pulses are different. In one embodiment, the pulse frequency of the first DC pulses and the pulse frequency of the second DC pulses are different. The pulse frequency of the DC pulses may be any suitable value, but are in the range from about 10 kHz to about 10 MHz in one embodiment.

The voltage of the first DC pulses may also be different or the same as the voltage of the second DC pulses. In one specific implementation, the substrate holder may be fed from a single DC power supply and the voltage at each of the conductors may be substantially the same. Of course, even using only one DC power supply does not preclude having different voltage parameters at one or more of the conductors since the voltage levels could be altered using internal circuitry.

The DC voltage may be pulsed in step 2102 and/or step 2103 as a series of pulse trains (i.e. groups of DC pulses). The pulse trains may have additional pulse parameters such as pulse train length and pulse train frequency. Since the pulse trains include DC pulses, the pulse train frequency may be lower than the pulse frequency of the constituent DC pulses, but may be any suitable value otherwise. In various embodiments, the DC voltage is pulsed as a series of pulse trains have a pulse train frequency ranging from about 1 Hz to about 100 kHz.

Optionally, step 2104 includes dynamically adjusting the second pulse parameters while pulsing the DC voltage to both the first conductor and the second conductor (i.e. concurrently with step 2101 and step 2103). Further, (e.g. as part of a plasma process), the concurrent steps (step 2102, step 2103, and the optional step 2104) may optionally be repeated in step 2105 immediately or after a delay. For example, the steps could be repeated immediately with different pulse parameters. Some implementations of the method 2100 may repeat the steps using the same pulse parameters after a delay. Of course, the pulse parameters may also be different even if step 2105 is delayed.

Example embodiments of the invention are summarized here. Other embodiments can also be understood from the entirety of the specification as well as the claims filed herein.

Example 1. A method of plasma processing including: delivering DC voltage to a substrate holder including an upper side configured to support a substrate disposed within a plasma processing chamber, the upper side being divided into a plurality of zones by a plurality of conductors electrically isolated from each other; pulsing the DC voltage as first DC pulses to a first conductor of the plurality of conductors using first pulse parameters; and pulsing the DC voltage as second DC pulses to a second conductor of the plurality of conductors using second pulse parameters different from the first pulse parameters while pulsing the DC voltage to the first conductor.

Example 2. The method of example 1, where the first pulse parameters include a first duty cycle of the first DC pulses, and the second pulse parameters include a second duty cycle of the second DC pulses that is different than the first duty cycle.

Example 3. The method of one of examples 1 and 2, where the first pulse parameters include a first voltage of the first DC pulses, and the second pulse parameters include a second voltage of the second DC pulses, the second voltage being equal to the first voltage.

Example 4. The method of one of examples 1 to 3, further including: dynamically adjusting the second pulse parameters while pulsing the DC voltage to both the first conductor and the second conductor.

Example 5. The method of one of examples 1 to 4, where pulsing the DC voltage as the first DC pulses includes pulsing the DC voltage as a series of pulse trains.

Example 6. The method of one of examples 1 to 5, where the plurality of zones includes a plurality of concentric zones, and where pulsing the DC voltage as the first DC pulses and the second DC pulses includes controlling radial process uniformity using the difference between the first pulse parameters and the second pulse parameters.

Example 7. The method of one of examples 1 to 6, where the plurality of zones includes a plurality of azimuthal zones, and where pulsing the DC voltage as the first DC pulses and the second DC pulses includes controlling azimuthal process uniformity using the difference between the first pulse parameters and the second pulse parameters.

Example 8. A plasma processing apparatus including: a plasma processing chamber; a substrate holder including an upper side configured to support a substrate disposed within the plasma processing chamber, the upper side being divided into a plurality of zones; a DC power supply coupled to the substrate holder with no intervening impedance matching network; and a controller operatively coupled to the plurality of zones and configured to pulse DC voltage from the DC power supply to each of the plurality of zones using corresponding independently selectable pulse parameters.

Example 9. The plasma processing apparatus of example 8, where the plurality of zones includes a plurality of concentric zones including a central zone and an edge zone surrounding the central zone.

Example 10. The plasma processing apparatus of example 9, where the edge zone is divided into a plurality of edge azimuthal segments.

Example 11. The plasma processing apparatus of one of examples 9 and 10, where the plurality of zones includes an interior zone surrounding the central zone between the edge zone and the central zone.

Example 12. The plasma processing apparatus of one of examples 8 to 11, where the plurality of zones includes a plurality of azimuthal segments each extending from a central point of the upper side to an edge of the upper side.

Example 13. The plasma processing apparatus of one of examples 8 to 12, where the plurality of switches are electronic switches including metal-oxide-semiconductor field-effect transistors.

Example 14. A substrate holder including: a holder assembly including an upper side configured to support a substrate disposed within a plasma processing chamber; a plurality of conductors electrically isolated from each other and disposed in the holder assembly at or below the upper side, the upper side being divided into a plurality of zones by the plurality of conductors; a plurality of switches disposed within the holder assembly, each of the plurality of switches being coupled to a corresponding one of the plurality of conductors; at least one power input coupled to the plurality of switches and configured to provide bias power to the plurality of conductors; and a plurality of control inputs each coupled to a corresponding switch of the plurality of switches and configured to toggle the corresponding switch between an ON state allowing the bias current to flow and an OFF state disallowing the bias current to flow.

Example 15. The substrate holder of example 14, where the plurality of switches are electronic switches including metal-oxide-semiconductor field-effect transistors.

Example 16. The substrate holder of one of examples 14 and 15, where the each of the plurality of switches is implemented as half bridge switches.

Example 17. The substrate holder of example 16, where the each of the plurality of switches includes a control signal input coupled to inputs of both an inverter and a buffer, a first transistor including a control terminal coupled to an output of the inverter, a first input/output terminal coupled to a reference voltage, and a second input/output terminal, a first diode coupled between the first and second input/output terminals of the first transistor, a second transistor including a control terminal coupled to an output of the buffer, a first input/output terminal, and a second input/output terminal coupled to a high voltage input, a second diode coupled between the first and second input/output terminals of the second transistor, and a high voltage output coupled to the second input/output terminal of the first transistor, the first input/output terminal of the second transistor, and both the first diode and the second diode.

Example 18. The substrate holder of one of examples 14 to 17, where the plurality of zones includes a plurality of concentric zones.

Example 19. The substrate holder of one of examples 14 to 18, where the plurality of zones includes a plurality of azimuthal zones.

Example 20. The substrate holder of one of examples 14 to 19, where the at least one power input is a single power input, the plurality of switches being configured to receive the bias power from the single power input.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of plasma processing comprising:
delivering direct current (DC) voltage to a substrate holder comprising an upper side configured to support a substrate disposed within a plasma processing chamber, the upper side being divided into a plurality of zones by a plurality of conductors electrically isolated from each other;
pulsing the DC voltage as first DC pulses to a first conductor of the plurality of conductors using first pulse parameters; and
pulsing the DC voltage as second DC pulses to a second conductor of the plurality of conductors using second pulse parameters different from the first pulse parameters while pulsing the DC voltage to the first conductor.

2. The method of claim 1, wherein
the first pulse parameters comprise a first duty cycle of the first DC pulses, and
the second pulse parameters comprise a second duty cycle of the second DC pulses that is different than the first duty cycle.

3. The method of claim 1, wherein
the first pulse parameters comprise a first voltage of the first DC pulses, and
the second pulse parameters comprise a second voltage of the second DC pulses, the second voltage being equal to the first voltage.

4. The method of claim 1, further comprising:
dynamically adjusting the second pulse parameters while pulsing the DC voltage to both the first conductor and the second conductor.

5. The method of claim 1, wherein pulsing the DC voltage as the first DC pulses comprises pulsing the DC voltage as a series of pulse trains.

6. The method of claim 1, wherein the plurality of zones comprises a plurality of concentric zones, and wherein pulsing the DC voltage as the first DC pulses and the second DC pulses comprises controlling radial process uniformity using the difference between the first pulse parameters and the second pulse parameters.

7. The method of claim 1, wherein the plurality of zones comprises a plurality of azimuthal zones, and wherein pulsing the DC voltage as the first DC pulses and the second DC pulses comprises controlling azimuthal process uniformity using the difference between the first pulse parameters and the second pulse parameters.

8. A plasma processing apparatus comprising:
a plasma processing chamber;
a substrate holder comprising an upper side configured to support a substrate disposed within the plasma processing chamber, the upper side being divided into a plurality of zones;
a direct current (DC) power supply coupled to the substrate holder with no intervening impedance matching network; and
a controller operatively coupled to the plurality of zones and configured to pulse DC voltage from the DC power supply to each of the plurality of zones using corresponding independently selectable pulse parameters.

9. The plasma processing apparatus of claim 8, wherein the plurality of zones comprises a plurality of concentric zones comprising a central zone and an edge zone surrounding the central zone.

10. The plasma processing apparatus of claim 9, wherein the edge zone is divided into a plurality of edge azimuthal segments.

11. The plasma processing apparatus of claim 9, wherein the plurality of zones comprises an interior zone surrounding the central zone between the edge zone and the central zone.

12. The plasma processing apparatus of claim 8, wherein the plurality of zones comprises a plurality of azimuthal segments each extending from a central point of the upper side to an edge of the upper side.

13. The plasma processing apparatus of claim 8, wherein the plurality of switches are electronic switches comprising metal-oxide-semiconductor field-effect transistors.

14. A substrate holder comprising:
a holder assembly comprising an upper side configured to support a substrate disposed within a plasma processing chamber;
a plurality of conductors electrically isolated from each other and disposed in the holder assembly at or below the upper side, the upper side being divided into a plurality of zones by the plurality of conductors;
a plurality of switches disposed within the holder assembly, each of the plurality of switches being coupled to a corresponding one of the plurality of conductors;
at least one power input coupled to the plurality of switches and configured to provide bias power to the plurality of conductors; and
a plurality of control inputs each coupled to a corresponding switch of the plurality of switches and configured to toggle the corresponding switch between an ON state allowing the bias current to flow and an OFF state disallowing the bias current to flow.

15. The substrate holder of claim 14, wherein the plurality of switches are electronic switches comprising metal-oxide-semiconductor field-effect transistors.

16. The substrate holder of claim 14, wherein the each of the plurality of switches is implemented as half bridge switches.

17. The substrate holder of claim 16, wherein the each of the plurality of switches comprises
a control signal input coupled to inputs of both an inverter and a buffer,
a first transistor comprising a control terminal coupled to an output of the inverter, a first input/output terminal coupled to a reference voltage, and a second input/output terminal,
a first diode coupled between the first and second input/output terminals of the first transistor,
a second transistor comprising a control terminal coupled to an output of the buffer, a first input/output terminal, and a second input/output terminal coupled to a high voltage input,
a second diode coupled between the first and second input/output terminals of the second transistor, and
a high voltage output coupled to the second input/output terminal of the first transistor, the first input/output terminal of the second transistor, and both the first diode and the second diode.

18. The substrate holder of claim 14, wherein the plurality of zones comprises a plurality of concentric zones.

19. The substrate holder of claim 14, wherein the plurality of zones comprises a plurality of azimuthal zones.

20. The substrate holder of claim 14, wherein the at least one power input is a single power input, the plurality of switches being configured to receive the bias power from the single power input.
